(19) United States
(12) Patent Application Publication
(10) Pub. No.: US 2014/0339615 A1
(43) Pub. Date: Nov. 20, 2014

(54) BSI CMOS IMAGE SENSOR

(71) Applicant: ViaEra Technologies Company Limited, Hsin-Chu City (TW)

(72) Inventors: Wei-Ko WANG, Longtan Township (TW); Chi-Han LIN, Zhubei City (TW); Zong-Ru TU, Keelung City (TW); Yu-Kun HSIAO, Hsin-Chu City (TW); Chih-Kung CHANG, Chu-Tung (TW)

(73) Assignee: ViaEra Technologies Company Limited, Hsin-Chu City (TW)

(21) Appl. No.: 13/895,819

(22) Filed: May 16, 2013

(51) Int. Cl. H01L 27/146

(52) U.S. Cl. CPC H01L 27/14621; H01L 27/1464
USPC 257/294

(57) ABSTRACT

A back surface illuminated image sensor is provided. The back surface illuminated image sensor includes: a first passivation layer disposed on the photodiode array; an oxide grid disposed on the first passivation layer and forming a plurality of holes exposing the first passivation layer; a color filter array including a plurality of color filters filled into the holes, wherein the oxide grid has a refractive index smaller than that of plurality of color filters; and a metal grid aligned to the oxide grid, wherein the metal grid has an extinction coefficient greater than zero.

### TECHNICAL FIELD

The present disclosure relates generally to an optoelectronic device, and more particularly to an BSI CMOS image sensor.

### BACKGROUND

Complementary metal oxide semiconductor (CMOS) image sensors are gaining in popularity over traditional charge-coupled devices (CCDs) due to certain advantages inherent in the CMOS image sensors. In particular, CMOS image sensors typically require lower voltages, consume less power, enable random access to image data, and may be fabricated with compatible CMOS processes.

CMOS image sensors utilize a photodiode array to convert light energy into electrical energy and can be designed to be illuminated from a front surface or from a back surface. The back surface illuminated (BSI) CMOS image sensors can optimize the optical path independent of the electrical wiring arrange and disturbance, such that the BSI CMOS image sensors can ultimately achieve higher quantum efficiency than the front surface illuminated CMOS image sensors that receive the incident light on the front side of semiconductor substrate which the electrical wiring layer is formed.

With the trend of size reduction of pixels of the BSI CMOS image sensors, each pixel receive lower amount of incident light and suffers more cross-talk with adjacent pixels. It is a demand to improve sensitivity and prevent cross-talk for further miniaturization requirements.

### SUMMARY

Accordingly, a back surface illuminated CMOS image sensor is provided. The back surface illuminated CMOS image sensor includes a first passivation layer disposed on a photodiode array; an oxide grid disposed on the first passivation layer and forming a plurality of holes exposing the first passivation layer; a color filter array including a plurality of color filters filled into the holes, wherein the oxide grid has a refractive index smaller than that of the plurality of color filters; and a metal grid aligned to the oxide grid, wherein the metal grid has an extinction coefficient greater than zero.

Accordingly, a back surface illuminated CMOS image sensor is provided. The back surface illuminated CMOS image sensor includes a plurality of unit pixels, each unit pixel includes a photodiode and at least one pixel transistor; a plurality of color filters on the unit pixels; a first passivation layer between the photodiodes and the color filters; an oxide grid including a trapezoid shape interposed between the color filters of the pixels; and a metal grid comprising a trapezoid shape aligned to the oxide grid, wherein the oxide grid has a refractive index smaller than, that of the plurality of color filters, and wherein the metal grid has an extinction coefficient greater than zero.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1A shows a cross-sectional view of an BSI CMOS image sensor according to an embodiment of the present disclosure;

FIG. 1B shows a top view of the BSI CMOS image sensor shown in FIG. 1A;

FIGS. 2-6 show cross-sectional views of an BSI CMOS image sensors according to various embodiments of the present disclosure.

### DETAILED DESCRIPTION

The following description is of the best-contemplated mode of carrying out the invention. This description is made for the purpose of illustrating the general principles of the invention and should not be taken in a limiting sense. For example, the formation of a first feature over, above, below, or on a second feature in the description that follows may include embodiments in which the first and second features are formed in direct contact, and may also include embodiments in which additional features may be formed between the first and second features, such that the first and second features may not be in direct contact. The scope of the invention is best determined by reference to the appended claims.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

The terminology used herein is for the purpose of describing particular example embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

A method for resolving the cross-talk issue is forming a metal grid disposed under color filters. The metal grid would absorb (or block) the incident light such that the incident light would not diffuse to the neighboring pixels. The cross-talk issue can be substantially reduced by the formation of the metal grid, but the quantum efficiency of the BSI CMOS image sensors is affected since a portion of the incident light absorbed by the metal grid cannot reach the photodiode array.

Embodiments according to the present disclosure disclose embodiments of an BSI CMOS image sensor which comprises a metal grid with an oxide grid for further enhancing the quantum efficiency while resolving the cross-talk, providing a high chief ray angle tolerance and improving sensitivity.

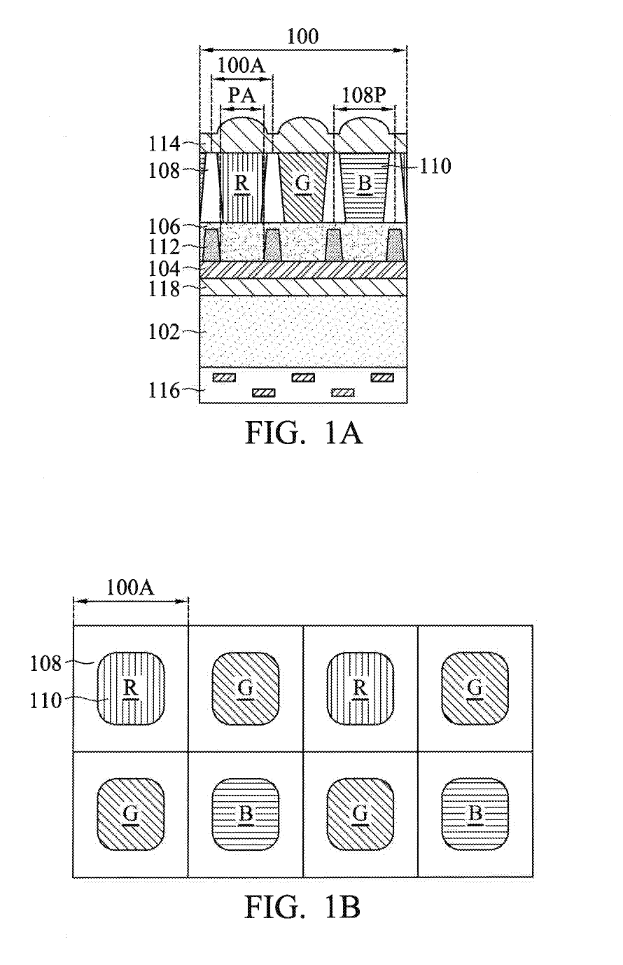

FIG. 1A shows a cross-sectional view of the BSI CMOS image sensor according to an embodiment of the present disclosure. In an embodiment, the BSI CMOS image sensor may comprise a pixel region 100 in which a plurality of unit pixels 100A is arranged in a semiconductor substrate made of silicon, and a peripheral circuit section (not shown) disposed in a periphery of the pixel region 100. A photodiode array 102 comprising a plurality of photodiodes and a plurality of pixel transistors (not shown) may be formed through of the overall region semiconductor substrate in the pixel region 100.

A first passivation layer 104 and a second passivation layer 106 may be disposed on the photodiode array 102. In an embodiment, the second passivation layer 106 may be disposed on the first passivation layer 104. The first passivation layer 104 and the second passivation layer 106 may be formed of the same or different materials. For example, the first and second passivation layers 104 and 106 may be formed of silicon oxide, silicon nitride, Ta₂O₅, HfO₂, or a combination thereof. The first and second passivation layers 104 and 106 may function as an etch stop layer during the fabrication of the peripheral circuit (not shown). In some embodiments, the first passivation layer 104 can be omitted if it is permitted by the fabricating process. Alternatively, another passivation layer 118 or more passivation layers may be formed between the passivation layers 104 and 106 and the photodiode array 102.

An oxide grid 108 may be disposed on the second passivation layer 106. The oxide grid 108 may be arranged periodically around the unit pixels 100A and form a plurality of holes exposing the second passivation layer 106. A color filter array 110 comprising a plurality of color filters 110 is filled into the holes. In an embodiment, the oxide grid 108 may have tapered sidewalls, and therefore the color filters 110 may have reverse-tapered sidewalls. As shown in FIG. 1A, the oxide grid 108 and the color filters 110 may have a trapezoid shape and a reversed trapezoid shape, respectively. For example, the oxide grid 108 may have a bottom surface wider than or equal to its top surface, and the color filters 110 may have a bottom surface narrower than their top surface.

In an embodiment, the top surfaces of the oxide grid 108 and the color filters 110 may be substantially level with each other. The oxide grid 108 may have a periodic interval 108P substantially equal to the width of the unit pixels 100A. The color filters 110 may at least comprise three primary colors, such as red, green and blue (R, G and B), and each of them may be arranged in any suitable combination. For example, referring to FIG. 1B, it shows a top view of the BSI CMOS image sensor shown in FIG. 1A while removing the microlens structure 114. Each photodiode 102 in the unit pixels 100A corresponds to one of the three primary colors, and the colors are alternately arranged. The oxide grid 108 may surround the color filters 110 for blocking the incident light diffusing to neighboring unit pixels 100A. As shown in FIG. 1B, the holes filled with the color filters 110 may be a square with rounded corners. Alternatively, the holes may have a circular shape.

In other words, the oxide gird 108 is a three-dimensional structure. The oxide grid 108 is made up of a series of intersecting perpendicular and horizontal axes for separating the adjacent color filters 110. In the cross-section view, the oxide grid 108 may be formed as a plurality of periodic parallel partitions, and the distance between two parallel partitions is substantially equal to the dimension of a unit pixel 100A.

A metal grid 112 may be embedded in the second passivation layer 106. For example, the metal grid 112 may stand on the first passivation layer 104 and align with the oxide grid 108. In addition, the metal grid 112 may be spaced apart from the oxide grid 108 and the color filters 110 by the second passivation layer 106 such that the oxide grid 108 may be protected by the second passivation layer 116. The metal grid 112 may be arranged periodically around the unit pixels 100A to prevent static electricity damage. The metal grid 112 may tapered sidewalls i.e., having a trapezoid shape in the cross-section vie . For example, the metal grid 112 may have a bottom surface wider than its upper surface, and the sidewalls of the metal grid may be inclined and have an angle of between about 50° and about 90° with the bottom of the metal grid. The metal grid 112 may have a height of between about 0.05 μm and about 1.0 μm. The metal grid 112 may have a bottom width of about 5.7% to about 30% of the periodic interval 108P of the oxide grid 108 (or the width of the unit pixels 100A). In an embodiment, the metal grid 112 may be formed of W, Cu, AlCu or a combination thereof.

In other words, the metal gird 112 is a three-dimensional structure. The metal grid 112 is made up of a series of intersecting perpendicular and horizontal axes and is aligned to the oxide grid 108. In the cross-section view, the metal grid 108 may be formed as a plurality of periodic parallel partitions.

The oxide grid 108 may have a refractive index greater than that of all of the color filters 110. The refractive index is a property of a material that changes the speed of light and is computed as the ratio of the speed of light in a vacuum to the speed of light through the material. When light travels at an angle between two different materials, their refractive indices determine the angle of transmission (refraction) of the light beam. In general, the refractive index varies based on the frequency of the light as well, thus different colors of light travel at different speeds. High intensities also can change the refractive index. In this embodiment, the color filters 110 of the RGB (or cyan, magenta, yellow or clear) may have different refractive indices, and the oxide grid 108 may have the refractive index smaller than that of either one of the color filters.

The metal grid 112 may have an extinction coefficient greater than zero for blocking the incident light diffusion. For example, the metal grid 112 may mainly block the incident light by absorbing it, and the oxide grid 108 may mainly block the incident light by reflecting it. The oxide grid 108 may reflect the incident light diffusion such that a portion of the incident light that may diffuse to neighboring pixels can be reflected back to the targeted unit pixels 100A. In addition, a portion of the incident light that may be absorbed by the metal grid 112 may be reflected by the oxide grid 108 before the incident light reaches the metal grid 112. Thus, by forming the oxide grid 108, the size of the metal grid 112 may be reduced without deteriorating the cross-talk, and a lower portion of the incident light may be absorbed by the metal grid 112. The BSI CMOS image sensor according to the present embodiment may have enhanced quantum efficiency with low cross-talk.

In addition, when compared to the conventional BSI CMOS image sensor (containing the metal grid only), the light-receiving area PA of the unit pixels 100A may not be reduced if the oxide grid 108 is not wider than the metal grid 112. In an embodiment, the oxide grid 108 may have a bottom width substantially equal to that of the metal grid 112. In addition, the light-receiving area PA of the unit pixels 100A may be enlarged since the size of metal grid 112 may be reduced.

A microlens structure 114 may be disposed on the color filter array 110 and the oxide grid 108 for focusing an incident light toward the photodiode array and reducing the incident light diffusion. An interconnection layer 116 may be formed on the back surface of the semiconductor substrate, independent of the optical path.

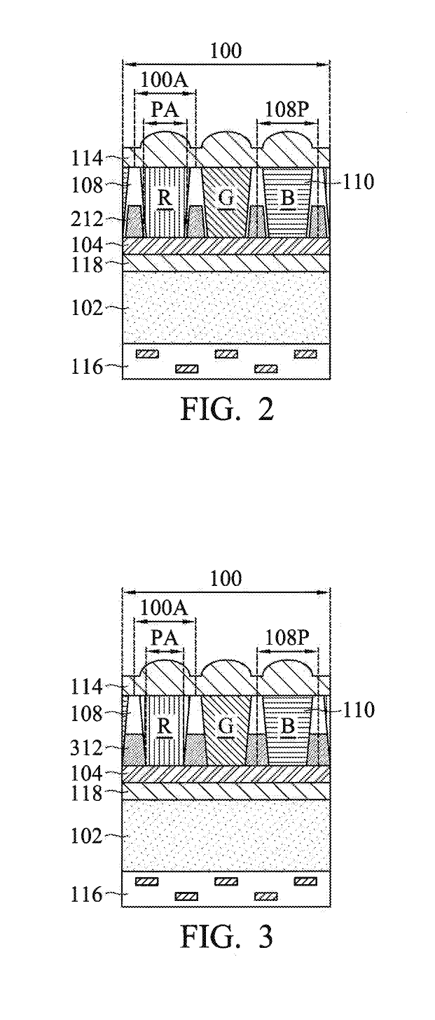

FIG. 2 shows a cross-sectional view of an BSI CMOS image sensor according to another embodiment of the present disclosure. In this embodiment, the BSI CMOS image sensor is similar to the BSI CMOS image shown in FIG. 1A except that the metal grid is embedded in the oxide gird. Like reference numerals in this embodiment are used to indicate elements substantially similar to the elements described in the above embodiments, and a detailed description of the substantially similar elements will not be repeated.

Referring to FIG. 2, the BSI CMOS image sensor may comprise a pixel region 100 in which a plurality of unit pixels 100A is arranged in a semiconductor substrate made of silicon, and a peripheral circuit section (not shown) disposed in a periphery of the pixel region 100. A photodiode array 102 comprising a plurality of photodiodes and a plurality of pixel transistors (not shown) may be formed through the overall region of the semiconductor substrate in the pixel region 100.

A first passivation layer 104 may be disposed on the photodiode array 102. The first passivation layer 104 may be formed of silicon oxide, silicon nitride, Ta₂O₅, HfO₂, or a combination thereof. The first passivation layer 104 may function as an etch stop layer during the fabrication of the peripheral circuit (not shown) In some embodiments, the first passivation layer 104 can be omitted if it is permitted by the fabricating process. Alternatively, another passivation layer 118 or more passivation layers may be formed between the first passivation layer 104 and the photodiode array 102.

An oxide grid 108 may be disposed on the passivation layer 104. The oxide grid 108 may be periodically arranged around the unit pixels 100A and form a plurality of holes exposing the first passivation layer 104. A color filter array 110 comprising a plurality of color filters 110 is filled into the holes. In an embodiment, the oxide grid 108 may have tapered sidewalls, and therefore the color filters 110 may have reverse-tapered sidewalls. For example, the oxide grid 108 may have a bottom surface wider than or equal to its top surface, and the color filters 110 may have a bottom surface narrower than its top surface. In an embodiment, the top surfaces of the oxide grid 108 and the color filters 110 may be substantially level with each other. The oxide grid 108 may have a periodic interval 108P substantially equal to the width of the unit pixels 100A. The color filters 110 may at least comprise three primary colors, such as red, green, and blue (R, G and B), with each arranged in any suitable combination.

A metal grid 212 may be embedded in the oxide grid 108. For example, the metal grid 212 may stand on the first passivation layer 104 and be surrounded by the oxide grid 108. The oxide grid 108 may have a bottom width wider than that of the metal grid 212 such that the metal grid 212 is spaced apart from the color filter array 110 by the oxide grid 108. The metal grid 212 may also have a trapezoid shape with sidewalls having a slope similar to the sidewalls of the oxide grid 108. The metal grid 212 may have a height smaller than that of the oxide grid 108. For example, the metal grid may have a height of between about 0.05 μm and about 1.0 μm. The metal grid 212 has a bottom width of about 5.7% to about 20% of the periodic interval 108P of the oxide grid 108 (or the width of the unit pixels 100A). In an embodiment, the metal grid 212 may be formed of W, Cu, AlCu or a combination thereof.

The oxide grid 108 may have a refractive index smaller than that of all of the color filters 110. In addition, the metal grid 212 may have an extinction coefficient greater than zero for blocking the incident light diffusion. For example, the metal grid 212 may mainly block the incident light by absorbing it, and the oxide grid 108 may mainly block the incident light by reflecting it. In this embodiment, the portion of the incident light that is not reflected by and penetrates into the oxide grid 108 may be absorbed by the metal grid 212. In addition, the BSI CMOS image sensor may have a reduced total thickness since the metal grid 212 is embedded in the oxide grid 108. Thus, the BSI CMOS image sensor may have high quantum efficiency and low cross-talk with a reduced total thickness.

A microlens structure 114 may he disposed on the color filter array 110 and the oxide grid 108 for focusing an incident light toward the photodiode array 102 and reducing the incident light diffusion. An interconnection layer 116 may be formed on the back surface of the semiconductor substrate, independent of the optical path.

FIG. 3 shows a cross-sectional view of an BSI CMOS image sensor according to yet another embodiment of the present disclosure. In this embodiment, the BSI CMOS image sensor is similar to the BSI image sensor shown in FIG. 2 except that the metal grid is interposed between the oxide grid and the color filters. Like reference numerals in this embodiment are used to indicate elements substantially similar to the elements described in the above embodiments, and thus a detailed description of the substantially similar elements will not be repeated.

Referring to FIG. 3, the oxide grid 108 and the metal grid 312 may be disposed in an upper portion and a lower portion, respectively, of holes formed by the color filters 110. The sidewalls of the metal grid 312 may directly contact the color filters 110. In this embodiment, a portion of the incident light that is not reflected by and penetrating into the oxide grid 108 may be absorbed by the metal grid 110. When compared to the BSI CMOS image sensor as shown in FIG. 2, the metal grid 312 may have a larger surface area which may further reduce the cross-talk,

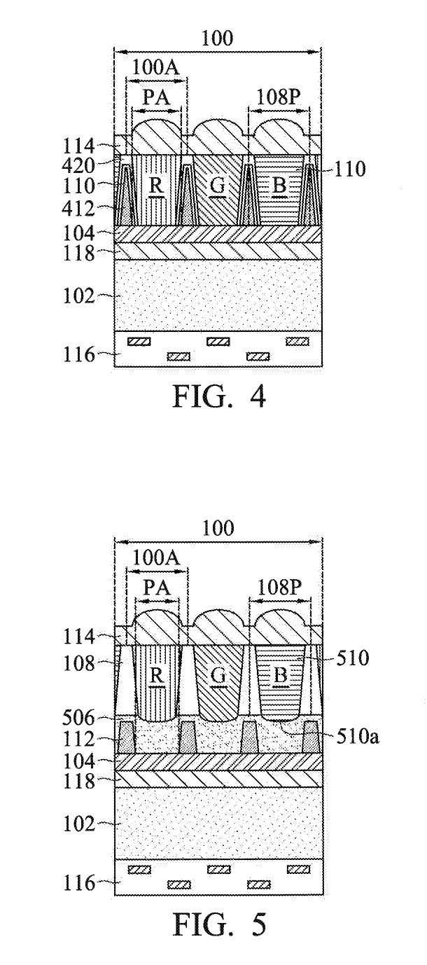

FIG. 4 shows a cross-sectional view of an BSI CMOS image sensor according to another embodiment of the present disclosure. In this embodiment, the BSI CMOS image sensor is similar to the BSI image sensor shown in FIG. 2 except that an additional grid may be interposed between the oxide grid and the color filters. Like reference numerals are used to indicate elements substantially similar to the elements described in the above embodiments, and thus a detailed description of the substantially similar elements will not be repeated.

Referring to FIG. 4, in addition to the metal grid and the oxide grid, an additional grid 420 may be interposed between the oxide grid 108 and the color filters 110. The additional grid 420 may surround the oxide grid 108 and have sidewalls directly contacting the color filters 110. The additional grid 420 may have a refractive index larger than that of the oxide grid 108. For example, the additional grid 420 may be formed of SiN, Ta₂O₅, HfO₂ or a combination thereof. Since the additional grid 420 may have a refractive index greater than that of the oxide grid 108, more portions of the incident light can be reflected by the additional grid 420 and the oxide grid 108, resulting in higher quantum efficiency.

FIG. 5 shows a cross-sectional view of an BSI CMOS image sensor according to an alternative embodiment of the present disclosure. In this embodiment, the BSI CMOS image sensor is similar to the BSI CMOS image sensor shown in FIG. 1 except that the color filters depress into the second passivation layer. Like reference numerals are used to indicate elements substantially similar to the elements described in the above embodiments, and thus a detailed description of the substantially similar elements will not be repeated.

Referring to FIG. 5, the color filters 510 and the second passivation layer 506 may have a concave interface 510A which depresses into the second passivation layer 506. In this embodiment, light beams cross the interface 510a between color filters 510 and the second passivation layer 506 that are formed of different materials and have different refractive indices. In order to achieve excellent color characteristics, the light-passing interface 510a can be concave (depressing into the second passivation layer 506). The shape of the interface is determined by the corresponding refractive indices of the color filters and the second passivation layer. For instance, if the color filter exhibits a larger refractive index than that of the second passivation layer, the interface respectively is concave and depressed into the second passivation layer. In this embodiment, the color filters 510 have a larger refractive index than that of the second passivation layer 506 while the light-passing interface 510a is concave.

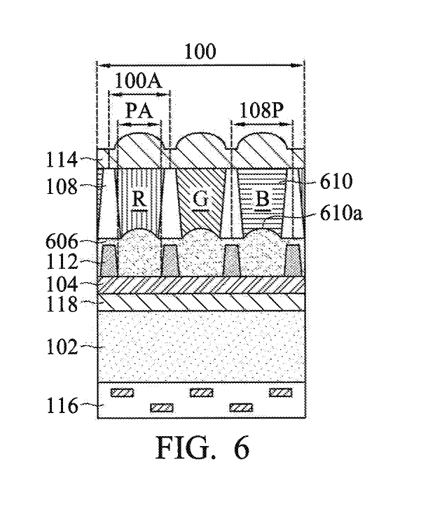

FIG. 6 shows a cross-sectional view of an BSI CMOS image sensor according to another alternative embodiment of the present disclosure. In this embodiment, the BSI CMOS image sensor is similar to the BSI CMOS image sensor shown in FIG. 1 except that an interface between the color filters and the second passivation layer is convex. Like reference numerals are used to indicate elements substantially similar to the elements described in the above embodiments, and thus a detailed description of the substantially similar elements will not be repeated.

Referring to FIG. 6, the color filters 610 and the second passivation layer 606 may have a convex interface 610A which depresses into the color filters 610. In this embodiment, light beams cross the interface 610a between color filters 610 and the second passivation layer 606 that are formed of different materials and have different refractive indices. In order to achieve excellent color characteristics, the light-passing interface 610a can be convex (bulging outwards from the second passivation layer 606). The shape of the interface is determined by the corresponding refractive indices of the color filters and the second passivation layer 606. For instance. For instance, if the color filter exhibits a smaller refractive index than that of the second passivation layer, the interface respectively is convex and bulging outwards from the second passivation layer. In this embodiment, the color filters 610 have a smaller refractive index than that of the second passivation layer 606 while the light-passing interface 610a is convex,

In other embodiments, the color filters and the second passivation layer may have the same refractive index with a flat interface between the color filters and the second passivation layer, as shown in FIGS. 1A-4.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

1. A back surface illuminated CMOS image sensor, comprising:
a first passivation layer disposed on a photodiode array;
an oxide grid disposed on the first passivation layer and forming a plurality of holes exposing the first passivation layer;
a color filter array comprising a plurality of color filters filled into the holes, wherein the oxide grid has a refractive index smaller than that of plurality of color filters, wherein the top surfaces of the oxide grid and the color filter array are level with each other; and
a metal grid aligned to the oxide grid, wherein the metal grid has an extinction coefficient greater than zero and the metal grid has a bottom width not larger than a bottom width of the oxide grid.

2. The back surface illuminated CMOS image sensor as claimed in claim 1, wherein the metal grid has a bottom surface wider than its top surface, wherein the sidewalls of the metal grid have a slope angle of about 50° to close to 90°.

3. The back surface CMOS illuminated image sensor as claimed in claim 1, wherein the metal grid has a bottom width of about 5.7% to about 30% of the periodic interval of the oxide grid.

4. The back surface illuminated CMOS image sensor as claimed in claim 1, further comprising a second passivation layer interposed between the oxide grid and the first passivation layer, and wherein the metal grid is embedded in the second passivation layer.

5. The back surface illuminated CMOS image sensor as claimed in claim 4, wherein the metal grid directly contacts the first passivation layer and is spaced apart from the oxide grid and the color filter array by the second passivation layer.

6. The back surface illuminated CMOS image sensor as claimed in claim 1, wherein the metal grid is embedded in the oxide grid and directly contacts the first passivation layer, wherein the bottom width of the oxide grid is wider than the bottom width of the metal grid.

7. The back surface illuminated CMOS image sensor as claimed in claim 6, wherein the metal grid is spaced apart from the color filter array by the oxide grid.

8. The back surface illuminated CMOS image sensor as claimed in claim 6, wherein the metal grid has a height smaller than that of the oxide grid.

9. The back surface illuminated CMOS image sensor as claimed in claim 1, wherein the metal grid is interposed between the oxide grid and the first passivation layer.

10. The back surface illuminated CMOS image sensor as claimed in claim 1, wherein the sidewalls of the metal grid are in direct contact with the sidewalls of the color filters.

11. The back surface illuminated CMOS image sensor as claimed in claim 1, wherein the color filters have a refractive index larger than that of the first passivation layer, and an interface between the color filters and the first passivation layer is concave.

12. The back surface illuminated CMOS image sensor as claimed in claim 1, wherein the color filters have a refractive index smaller than that of the first passivation layer, and an interface between the color filters and the first passivation layer is convex.

13. The back surface illuminated CMOS image sensor as claimed in claim 4, wherein the color filters have a refractive index larger than that of the second passivation layer, and an interface between the color filters and the second passivation layer is concave.

14. The back surface illuminated CMOS image sensor as claimed in claim 4, wherein the color filters have an refractive index smaller than that of the second passivation layer, and a interface between the color filters and the second passivation layer is convex.

15. The back surface illuminated CMOS image sensor as claimed in claim 1, further comprising an additional grid between the color filters and the oxide grid, wherein the additional grid has a refractive index larger than that of the oxide grid and the color filters.

16. The back surface illuminated CMOS image sensor as claimed in claim 1, further comprising a third passivation layer interposed between the first passivation layer and the photodiode array.

17. A back surface illuminated CMOS image sensor, comprising:
a plurality of unit pixels, each unit pixel comprising a photodiode and at least one pixel transistor;
a plurality of color filters on the unit pixels;
a first passivation layer between the photodiodes and the color filters;
an oxide grid comprising a trapezoid shape interposed between the color filters of the unit pixels, wherein the top surfaces of the oxide grid and the color filter array are level with each other; and
a metal grid comprising a trapezoid shape aligned to the oxide grid, wherein the oxide grid has a refractive index smaller than that of the plurality of color filters, and wherein the metal grid has an extinction coefficient greater than zero and the metal grid has a bottom width not larger than a bottom width of the oxide grid.

18. The back surface illuminated CMOS image sensor as claimed in claim 17, wherein the metal grid has a bottom width of about 7% to about 25% of the width of the pixels.

19. The back surface illuminated CMOS image sensor as claimed in claim 17, wherein the metal grid is embedded in the oxide grid or in a second passivation layer, and wherein the second passivation layer is interposed between the oxide grid and the first passivation layer.

20. The back surface illuminated CMOS image sensor as claimed in claim 17, wherein an interface between the color filters and the first passivation layer is concave or convex.
